(19) United States
(12) Patent Application Publication
(10) Pub. No.: US 2005/0269286 A1
(43) Pub. Date: Dec. 8, 2005

(54) Method of fabricating a nano-wire

(76) Inventors: Manish Sharma, Sunnyvale, CA (US); Si-Ty Lam, Pleasanton, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/864,004

(22) Filed: Jun. 8, 2004

(51) Int. Cl. H01L 21/302; B44C 1/22

(52) U.S. Cl. 216/11; 216/2; 216/58; 216/79; 438/706; 438/712; 438/718

(57) ABSTRACT

The present invention provides a method of fabricating a nano-wire from a substrate. The method includes the step of etching the substrate to form a wire that projects from a surface of the etched substrate. The wire has a predetermined thickness. The method also includes the step of exposing side surface portions of the wire to a reactive gas to react material of the side portions with the reactive gas and form a reaction product. The method further includes the step of removing the reaction product to thin the wire below the predetermined thickness.

### FIELD OF THE INVENTION

The present invention relates generally to a method of fabricating a nano-wire and more specifically, thought not exclusively, to a method of forming an array of nano-wires.

### BACKGROUND OF THE INVENTION

The ongoing performance increase of integrated electronic devices typically requires an increase in device density. Accordingly, there is a constant need to improve fabrication techniques that allow for a scale reduction of electronic components.

For some applications, such as field emission displays, particular transistor arrangements and other highly integrated devices it would be particularly advantageous to reduce the scale below the lithographic limit (50-80 nm). However, this is a challenge for device fabrication.

A field emission display, for example, includes an array of several thousand electron field emitters. Each of these electron field emitters is positioned in a vacuum. During use, an electric field is applied to a tip of the emitter resulting in the field emission of electrons and the controlled field emission is utilised to display information. In such a display each pixel corresponds to an electron field emitter.

In general each electron field emitter needs to have a very sharp tip in order to provide the geometry required for the generation of an electrical field which is high enough at the tip to overcome the work function of the tip material and to enable emission of electrons.

Field emission electrodes are also used for electron microscopes but in this case only one field emission electron source is required. Technologies have been developed to prepare single tips for such electron field emitters which have a tip diameter that is tapered to a few atoms. However, the preparation of an entire array of field emission emitters is significantly more problematic. For example, narrow tips may be formed from nano-wire. Unfortunately, nano-wires are typically seed-grown and therefore cannot be placed at the desired positions. Consequently the preparation of an array of such nano-wires can be very difficult.

With lithography it is possible to fabricate an array of micro-structures with each micro-structure being positioned at a desired position. However, the lithographic limit is 50-80 nm and structures having a size that is determined by lithography cannot have a size smaller than that.

Accordingly, there is a need for a technique that enables the fabrication of narrow nano-wires at desired positions.

### SUMMARY OF THE INVENTION

Briefly, an embodiment of the present invention provides a method of fabricating a nano-wire from a substrate. The method includes the step of etching the substrate to form a wire that projects from a surface of the etched substrate wherein the wire has a predetermined thickness. The method also includes the step of exposing side surface portions of the wire to a reactive gas to react material of the side portions with the reactive gas and form a reaction product. The method further includes the step of removing the reaction product to thin the wire below the predetermined thickness.

The invention will be more fully understood from the following description of embodiments of the invention. The description is provided with reference to the accompanying drawings.

### BRIEF DESCRIPTION OF THE DRAWINGS

FIGS. 1A to 1F are cross-sectional diagrams illustrating the fabrication of a nano-wire according to an embodiment of the present invention, and FIG. 1G is an array of nano-wires according to another embodiment;

FIG. 2 is a flow chart for a method embodiment;

FIGS. 3A to H illustrate the fabrication of a nano-wire according to an embodiment, and FIG. 3J is an array of nano-wires according to an embodiment;

FIG. 4 is a flow chart of a method embodiment; and

FIG. 5 is a field emission display according to an embodiment.

### DETAILED DESCRIPTION OF EMBODIMENTS

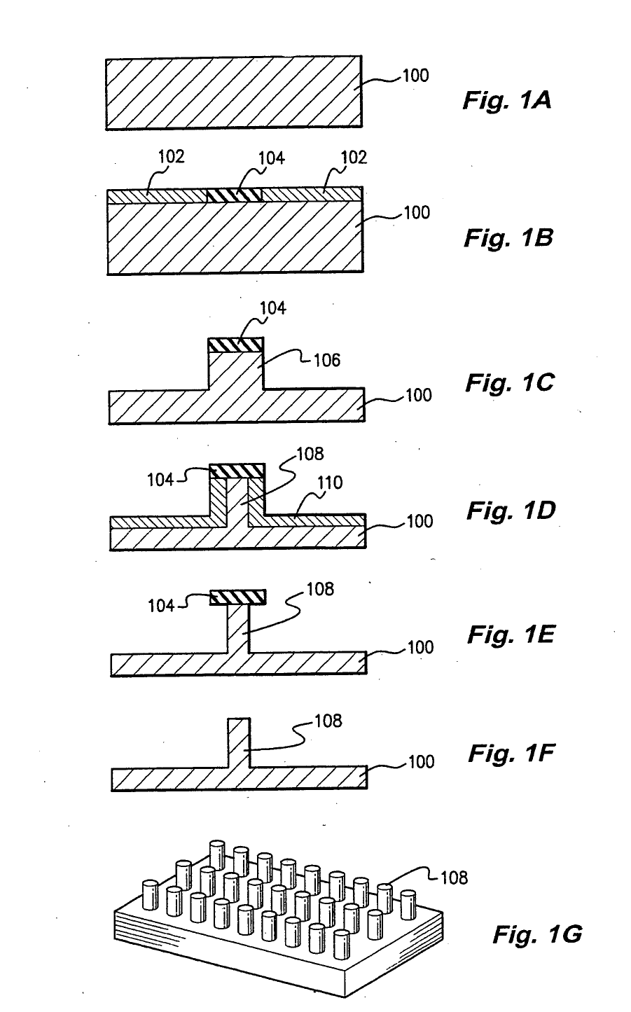

Referring to FIG. 1A to 1F, a method of fabricating a nano-wire is now described. Substrate 100 is coated with a protective layer 102 which is patterned and processed so that the area 104 of the protective layer is resistant to etching. The layer 102 and some of the underlying substrate material is then etched away using an anisotropic etch process so that a pillar 106 is formed below the protective layer 104. The substrate 100 including the pillar 106 is then exposed to oxygen to oxygenate the surface of the substrate 100 and the pillar 106. Consequently the non-oxidized portion 108 of the pillar is now thinner than the original pillar 106. The oxide layer 110 is then etched away and the layer 104 is removed. This etching process could be a wet etching process but is in this case is a dry etching process that involves ion etching. In this embodiment the etching process is a reactive ion etching process. In reactive ion etching, a combination of chemical action and ion bombardment is used to predominantly etch a particular chemical species such as the oxide of oxide layer 110. In this embodiment, chemical and physical parameters of the reactive ion etching process are selected so that predominantly the oxide layer 110 is etched.

For example, the substrate 100 may be processed using lithography so that the diameter of the area 104 approximates the lithographic limit such as 50 to 80 nm. Because the surface of the pillar 108 is oxidised and the oxide is removed using a reactive ion etch process, the pillar 108, or the “nano-wire”, can have a thickness that is smaller than 50 to 80 nm. For example, the thickness may be of the order of 20 nm or less than that. With the above-described method it is possible to form such a nano-wire at a desired position.

FIG. 1G shows an array 110 of the nano-wires 108 and each nano-wire 108 was produced using the method as illustrated in FIG. 1A to 1F and described above. The substrate 100 typically is composed of silicon but may alternatively include any other material that forms a reaction product with a reactive gas. For example, substrate 100 may include another semiconductor material that forms an oxide or a nitride, nitrate or nitride when exposed to oxygen or nitrogen respectively. The substrate 100 may also be doped with a dopant having a concentration gradient so that the nano-wire 108 has the same dopant concentration gradient along its length.

Examples for the material of the substrate 100 include semiconductor materials such a silicon (doped and undoped), silicides or Ir, Ta, Pd, Hf, W, TaN and silicon nitrite (doped and undoped). The protective layer 102 and 104 includes a metallic layer such as copper, gold, or aluminium. The anisotropic etch process that forms pillar 106, such as a deep silicon reactive ion etching process (trench etching), may be conducted so that pillar 106 has a height of 100 nanometres to 5 μm.

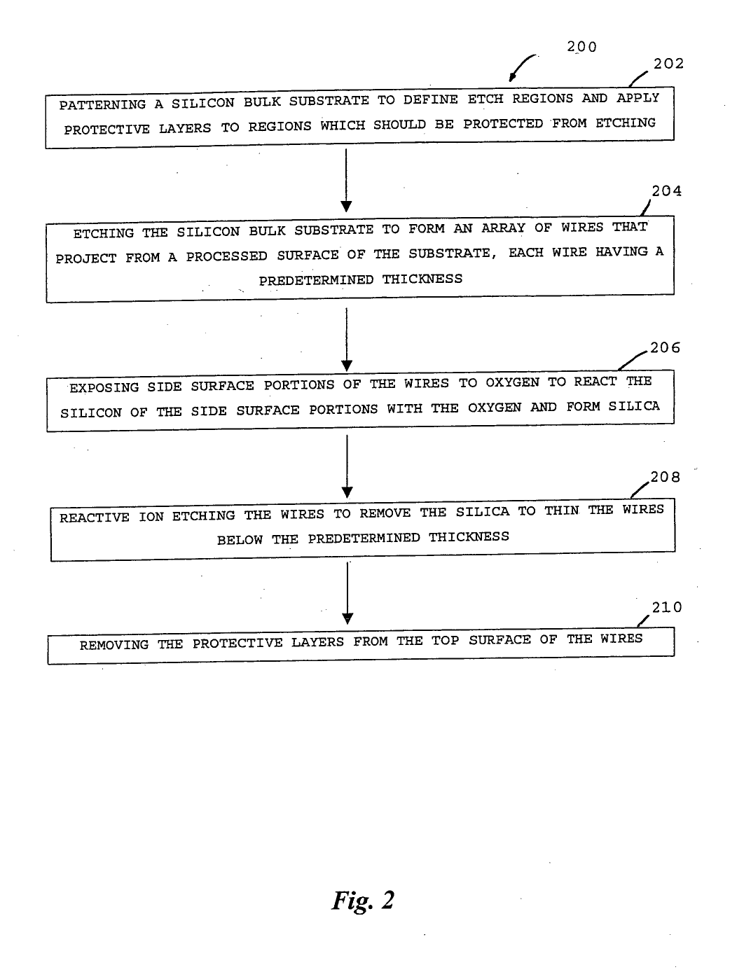

FIG. 2 summarizes some of the method steps used to fabricate an array of nano-wires. Initially a protective layer is applied to a silicon substrate and the substrate is patterned to define etch regions (step 202). The method also includes the step 204 of etching the silicon substrate to form an array of wires that project from a processed surface of the substrate. Each wire has a predetermined thickness. In step 206 side surface portions of the wires are exposed to oxygen to react with the oxygen and form silica. The method 200 also includes the step 208 of reactive ion etching the wires to remove the silica to thin the wires below a pre-determined thickness In step 210 the protective layers are removed from the top surfaces of the wires.

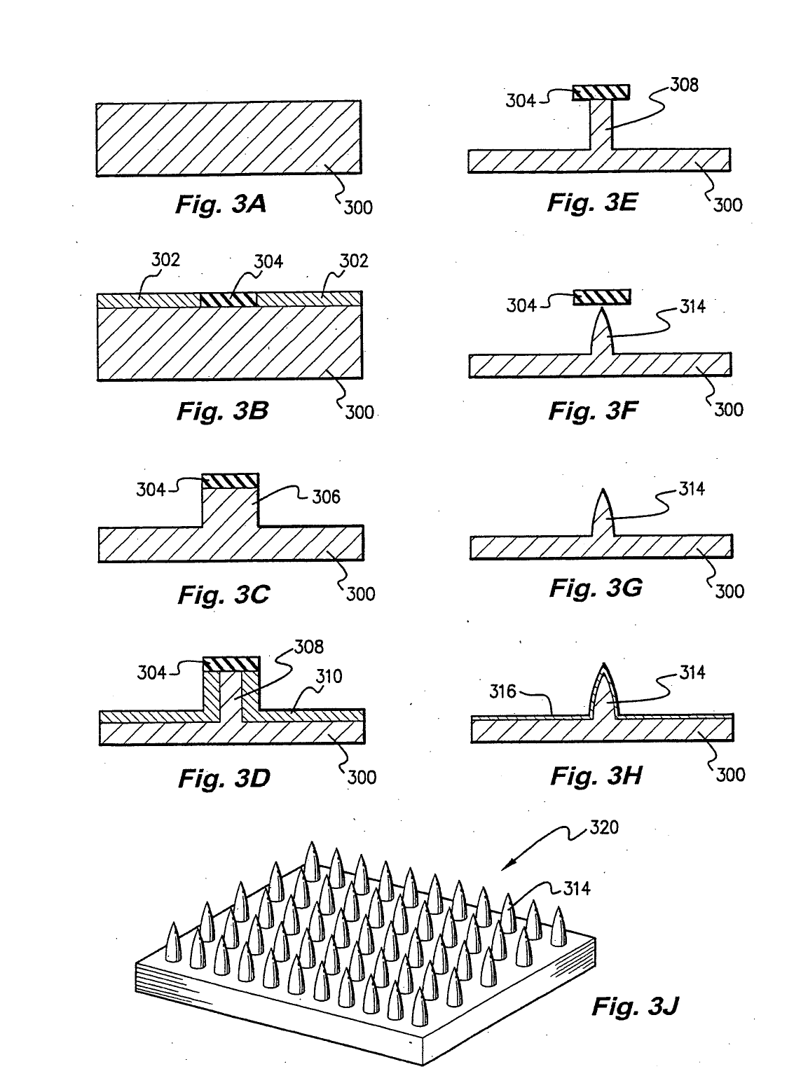

FIGS. 3A to 3H illustrate a method of fabricating a nano-wire according to another embodiment. In general, this embodiment is related to the embodiment illustrated in FIG. 1. Initially a substrate 300 is coated with a protective layer 302. The protective layer 302 is then covered with a photo-resist and processed using lithography so that the area 304 of the protective layer is resistant to anisotropic etch process. Layer 302 is then etched away around the area 304 together with some substrate material underlying the layer 302 so that pillar 306 is formed. Surface portions of the pillar 306 and of the substrate 300 are then oxidized so that an oxide layer 310 is formed which is removed using a reactive ion etching process.

As for the example illustrated in FIG. 1, the protective layer 304 may have a width that is close to the lithographic limit, such as 50 to 80 nanometres. Consequently the pillar 306 will have the same width. Because the oxide layer 310 is removed, a nano-wire 312 is formed that has a width that is less than 50 to 80 nm such as 20 nm or less.

The nano-wire 312 is then profiled using an undercutting isotropic etch process that is conducted so that a nano-wire 314 having a sharp tip is formed. The isotropic process may be a wet-etch process, but typically is a reactive ion etch process in which the etch parameters are chosen so that the etch process is isotropic. The protective layer potion 304 is then removed. The nano-wire 314 and the substrate 300 are then slightly oxidized so that a thin protective oxide layer 316 is formed.

In this embodiment the nano-wires 314 are formed using the anisotropic process so that the tip is sharp enough so that the nano-wire 314 can be used as an electron source for the field emission of electrons. In general the materials of the substrate 300 and the protective layer 302 are the same as those of the substrate 100 and the protective layer 102 described above and illustrated in FIG. 1.

FIG. 3J shows an array 320 of the profiled nano-wires 314. Each nano-wire 314 was fabricated using the process described above and illustrated in FIG. 3A to 3H. As the nano-wires 314 of the array 320 can be precisely placed and may have very sharp tips, the array 320 may be used for a broad range of applications, in particular for applications that need arrayed electron field emitters. For example, the array 320 may provide arrayed field emission electron emitters for an electron emission display. Further, the array 320 may be used for other devices in which arrayed electron emitters could replace individual electron emitters. Examples include electron beam lithography systems, scanning electron microscopes (SEM), microwave amplifiers that uses electron emitters or sensing device that use electron field emitters.

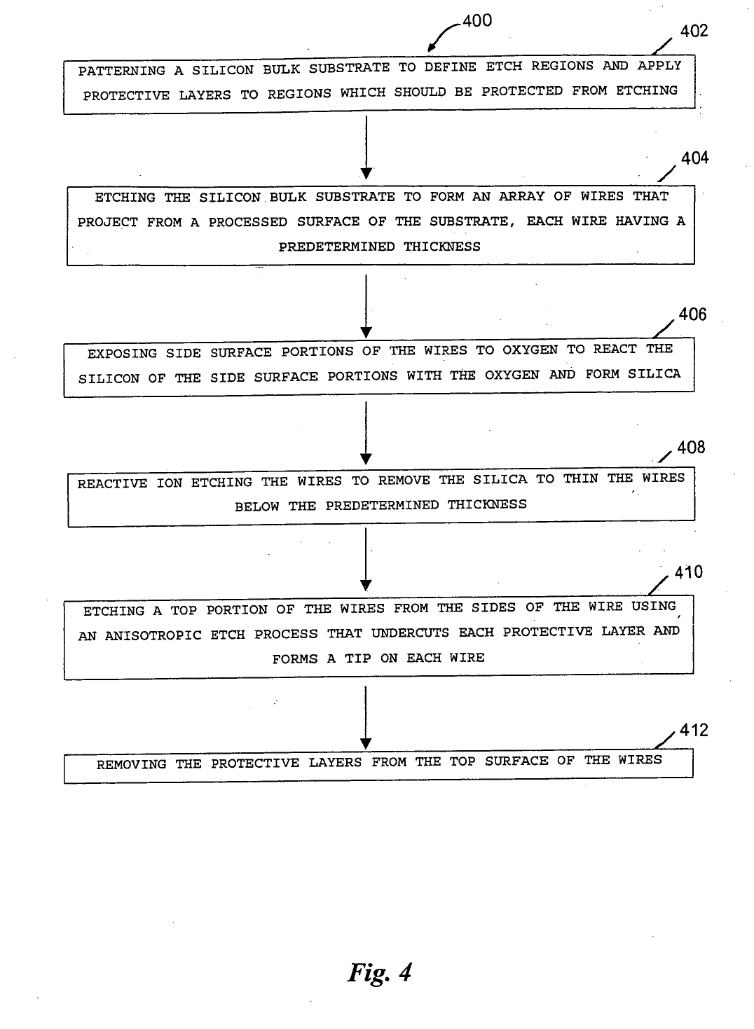

FIG. 4 illustrates steps of a method embodiment of forming an array of nano-wires such as the array 320 shown in FIG. 3J. The method 400 includes the initial step 402 of applying a protective layer to a silicon substrate and patterning the substrate to define etch regions. Step 404 includes etching the silicon substrate to form an array of wires. Each wire has a pre-determined thickness. The method also includes the step 406 of exposing side surface portions of the wires to oxygen to react the silicon of the side portions with the oxygen and, form silica. Further, the method 400 includes the step 408 of reactive ion etching the wires to remove the silica to thin the wires below the pre-determined thickness. Step 410 includes etching a top portion of the wires from the sides of the wires using an anisotropic etch process that undercuts each protective layer and forms a tip on each wire. The protective layers are then removed (step 412).

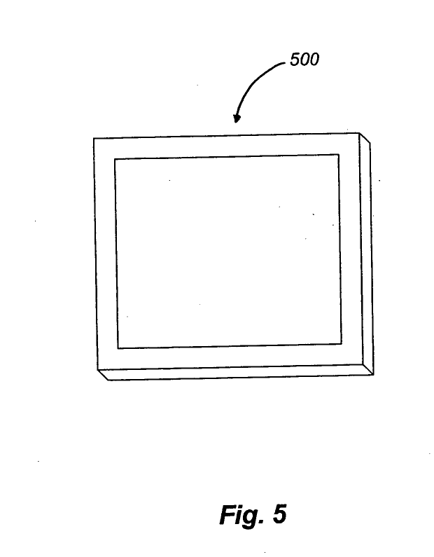

FIG. 5 shows a field emission display 500. The field emission display 500 includes an array of field emission electron emitter such as array 320 shown in FIG. 3J (for clarity the array of field emission electron emitters is not shown in FIG. 5).

Although the embodiments have been described with reference to particular examples, it is to be appreciated by those skilled in the art that the embodiments may take other forms. For example, the side portions of the pillars 106 or 306 may not be exposed to oxygen but to nitrogen so as to form a nitrogen compound on the surface which is then removed using an a reactive ion etch process. Again, the removal of the nitrogen compound enables the fabrication of a nano-wire having a thickness that is below the lithographic limit.

Further, the pillars 106 and 306 may not have a thickness that is of the order of the lithographic limit such as 50 to 80 nanometres but may be thicker. The nano-wires 108 and 312 may also not necessarily have a thickness smaller than 50-80 nm but may alternatively have a thickness above the lithographic limit or 50-80 nm. It is also to be understood that layer 304 may be removed prior to formation of nano-wire 314 with tip.

1. A method of fabricating a nano-wire from a substrate comprising the steps of:
etching the substrate to form a wire that projects from a surface of the etched substrate, the wire having a predetermined thickness;
exposing side surface portions of the wire to a reactive gas to react material of the side surface portions with the reactive gas and form a reaction product; and
removing the reaction product to thin the wire below the predetermined thickness.

2. The method of claim 1 comprising an additional step of profiling the wire using an etch processes.

3. The method of claim 2 wherein:
the step of profiling the wire comprises etching the side surface portions in a top region of the wire to form a tip.

4. The method of claims 3 wherein:
the wire is formed with a protective layer covering a top surface of the wire to prevent etching from the top of the wire.

5. The method of claim 4 wherein:
the step of profiling the wire comprises etching the side surface portions in a top region using an isotropic etch process that undercuts the protective layer and forms the tip.

6. The method of claim 1 wherein:
the substrate is a silicon wafer.

7. The method of claim 1 wherein:
the substrate comprises at least one of the materials Ir, Ta, Pd, Hf, W, TaN and doped silicon nitride.

8. The method as claimed in claim 5 wherein:
the protective layer comprises a metallic material.

9. The method of claims 1 wherein:
the reactive gas comprises oxygen and the reaction product is an oxide.

10. The method of claim 1 wherein:
the step of removing the reaction product comprises reactive ion etching (RIE).

11. The method of claim 1 wherein:
the wire is processed and the reactant is removed so that the formed nano-wire has a thickness of less than 50 nm.

12. The method as claimed in claim 1 wherein:
the substrate comprises a doped semiconductor material that has a dopant concentration gradient and the nano-wire fabricated from the substrate has a dopant concentration gradient in a direction along the elongation of the nano-wire.

13. The method of claim 1 comprising the additional step of reacting the nano-wire with oxygen so that the nano-wire is covered by an oxide layer.

14. A method of fabricating an array of nano-wires from a substrate comprising the steps of:
etching the substrate to form an array of wires that projects from a surface of the etched substrate, the wires having a predetermined thickness;
exposing side surface portions of the wires to a reactive gas to react material of the side surface portions with the reactive gas and form a reaction product; and
removing the reaction product to thin the wires below the predetermined thickness.

15. The method of claim 14 comprising an additional step of profiling each wire by etching the side surface portions in a top region of each wire in a manner so that an array of tips is formed.

16. The method of claims 15 wherein:
each wire is formed with a protective layer covering a top surface of the of the wire, the protective layer protecting the top surface of the wire from etching from the top, and the step of profiling the wires comprises etching the side surface portions in a top region of each wire using an anisotropic etch process that undercuts the protective layers and forms the tips.

17. A method of fabricating a field emission electron emitter from a substrate comprising the steps of:
etching the substrate to form a wire that projects from a surface of the processed substrate, the wire having a predetermined thickness; exposing the side surface portions of the wire to a reactive gas to react material of the side surface portions with the reactive gas and form a reaction product;
removing the reaction product from the wire to thin the wire below the predetermined thickness; and
profiling the wire using an etch processes in a manner so that a tip is formed form which in use electron are emitted.

18. A method of fabrication a field emission display comprising an array of field emission electron emitters, the method comprising the steps of:
etching the substrate to form an array of wires that projects from a surface of the processed substrate, each wire having a predetermined thickness;
exposing the side surface portions of each wire to a reactive gas to react material of the side surface portions with the reactive gas and form a reaction product;
removing the reaction product from each wire to thin the wires below the predetermined thickness; and
profiling the wires using an etch process in a manner so that that the side surface portions are etched to form a tip from which in use electrons are emitted.

19. An array of field emission emitters comprising:
a surface supporting the array, each field emission electron emitter comprising a nano-wire projecting from the surface, each nano-wire having a stem of a thickness of less than 50 nm and each nano-wire having a tip on the stem from which in use electrons are emitted.

20. The array of field emission emitters of claim 20 wherein:
the thickness of each stem is less than 40 nm.

21. A field emission display comprising:
an array of field emission electron emitters;
a surface supporting the array, each field emission electron emitter comprising a nano-wire projecting from the surface, each nano-wire having a stem of a thickness of less than 50 nm and each nano-wire having a tip on the stem from which in use electrons are emitted.

22. The field emission display of claim 21 wherein:
the thickness of each stem is less than 40 nm.
